(19) United States
(12) Patent Application Publication
(10) Pub. No.: US 2026/0363055 A1
(43) Pub. Date: Nov. 12, 2026

(54) SEMICONDUCTOR DEVICE AND METHOD FOR MANUFACTURING THE SAME

(71) Applicant: Samsung Electronics Co., Ltd., Suwon-si (KR)

(72) Inventors: Hangyeol Choi, Suwon-si (KR); Donghyun Ko, Suwon-si (KR); Jongsun Yoon, Suwon-si (KR); Sungjoo An, Suwon-si (KR); Woojin Lee, Suwon-si (KR); Sunguk Jang, Suwon-si (KR)

(73) Assignee: Samsung Electronics Co., Ltd., Suwon-si (KR)

(21) Appl. No.: 19/381,536

(22) Filed: Nov. 6, 2025

(30) Foreign Application Priority Data
May 7, 2025 (KR) 10-2025-0059361

(51) Int. Cl. H10W 20/41; H10W 20/00; H10W 20/42; H10W 20/43; H10W 20/47

(52) U.S. Cl. CPC H10W 20/435; H10W 20/42; H10W 20/43; H10W 20/47; H10W 20/075; H10W 20/077; H10W 20/098

(57) ABSTRACT

Provided is a semiconductor device including a first insulating layer on a substrate, a conductive pattern on the first insulating layer, and a first capping pattern on an upper surface of the conductive pattern. The conductive pattern includes a first region vertically overlapping the first capping pattern, and a second region surrounded by the first region. With respect to a first direction parallel to an upper surface of the substrate, a first distance between outer side surfaces of the first capping pattern is less than a first width of a lower surface of the conductive pattern.

### CROSS-REFERENCE TO RELATED APPLICATIONS

This present application claims priority to and the benefit under 35 U.S.C. § 119(a)-(d) of Korean Patent Application No. 10-2025-0059361, filed on May 7, 2025, in the Korean Intellectual Property Office, the entire disclosure of which is incorporated herein by reference.

### FIELD

The present disclosure herein relates to a semiconductor device and a method for manufacturing the same, and more particularly, to a semiconductor device with improved productivity and a method for manufacturing the same.

### BACKGROUND

A semiconductor device includes an integrated circuit composed of metal-oxide-semiconductor field effect transistors (MOSFET). As a size and a design rule of the semiconductor device are gradually decreasing, scaling down of the metal-oxide-semiconductor field effect transistors is also gradually being accelerated. As the metal-oxide-semiconductor field effect transistors are gradually scaled down, operation characteristics of the semiconductor device may be deteriorated. Accordingly, research on various methods for overcoming limitation caused by high-integration of the semiconductor device and forming the semiconductor device with more excellent performance is being conducted.

### SUMMARY

The present disclosure provides a semiconductor device with improved productivity and a method for manufacturing the same.

A technical goal of the disclosed concepts is not limited to the goal mentioned above, and other technical goals that are not mentioned may be clearly understood from description below by those skilled in the art.

Embodiments of the disclosed concepts provide a semiconductor device including a first insulating layer on a substrate, a conductive pattern on the first insulating layer, and a first capping pattern on an upper surface of the conductive pattern, wherein the conductive pattern includes a first region vertically overlapping the first capping pattern, and a second region surrounded by the first region, and with respect to a first direction parallel to an upper surface of the substrate, a first distance between outer side surfaces of the first capping pattern is less than a first width of a lower surface of the conductive pattern.

In embodiments of the disclosed concepts, a semiconductor device includes a first insulating layer on a substrate, a conductive pattern on the first insulating layer, and a first capping pattern vertically overlapping the conductive pattern on an upper surface of the conductive pattern, wherein with respect to a first direction parallel to an upper surface of the substrate, a first distance between outer side surfaces of the first capping pattern is less than a first width of a lower surface of the conductive pattern, and with respect to the first direction, a second distance between inner side surfaces of the first capping pattern is less than a second width of the upper surface of the conductive pattern.

In embodiments of the disclosed concepts, a semiconductor device includes an element layer on a substrate, and a line layer on the element layer, wherein the line layer includes a first insulating layer on the element layer, a conductive pattern on the first insulating layer, a first capping pattern on an upper surface of the conductive pattern, a second capping pattern on a side surface of the first capping pattern, and an air gap between the second capping pattern and the first insulating layer, and on a side surface of the conductive pattern, the conductive pattern includes a first region vertically overlapping the first capping pattern, and a second region surrounded by the first region, and with respect to a first direction parallel to an upper surface of the substrate, a first distance between outer side surfaces of the first capping pattern is less than a first width of a lower surface of the conductive pattern.

In embodiments of the disclosed concepts, a method for manufacturing a semiconductor device includes forming a conductive layer on a substrate, forming hard mask patterns on the conductive layer, forming a protective layer covering an upper surface of the conductive layer, forming first capping patterns covering upper surfaces and side surfaces of the hard mask patterns, removing the protective layer, and forming conductive patterns by partially removing the conductive layer by using the hard mask patterns and the first capping patterns as masks.

In embodiments, the upper surface of the conductive layer may be a first upper surface, the hard mask patterns may cover a second upper surface of the conductive layer, and the protective layer may be selectively formed on the first upper surface of the conductive layer.

In embodiments, the first capping patterns may be selectively formed on upper surfaces and side surfaces of the hard mask patterns.

In embodiments, during a process of forming the conductive patterns, each of the first capping patterns may be partially removed to expose upper surfaces of the hard mask patterns.

In embodiments, the protective layer may be interposed between the hard mask patterns.

In embodiments, the first capping patterns may be spaced apart from one another.

In embodiments, each of the first capping patterns may include at least one of SiOC, SiO, AlO, AlN, AlSiN, AlSiO, HfO, TiO, TiN, SiN, SiON, SiC, SiCN or ZrO.

In embodiments, the protective layer may include a first material, or a first material and a second material, the first material may include at least one of carbon, hydrogen or oxygen, and the second material may include at least one of nitrogen, halogen, sulfur or silicon.

In embodiments, the method for manufacturing a semiconductor device may further include forming a sacrificial layer between the conductive patterns, forming a second capping pattern on the sacrificial layer and forming an air gap between the conductive patterns by removing the sacrificial layer.

In embodiments, the conductive layer may be spaced apart from the first capping patterns by the protective layer.

### BRIEF DESCRIPTION OF THE DRAWINGS

The accompanying drawings are included to provide a further understanding of the disclosed concept, and are incorporated in and constitute a part of this specification. The drawings illustrate embodiments of the disclosed concepts and, together with the description, serve to explain principles of the disclosed concepts. In the drawings:

FIG. 1 is a cross-sectional view illustrating a semiconductor device according to some embodiments of the disclosed concepts;

FIG. 2 is a cross-sectional view partially illustrating a line layer of the semiconductor device of FIG. 1;

FIG. 3A is a plan view illustrating a first capping pattern and a conductive pattern of FIG. 2;

FIG. 3B is an enlarged diagram corresponding to P1 of FIG. 2, and specifically, is an enlarged diagram of a conductive pattern, a first capping pattern and a second insulating layer;

FIGS. 4 to 8 are each a cross-sectional view partially illustrating a line layer of the semiconductor device of FIG. 1;

FIGS. 9 to 14 are diagrams illustrating a method for manufacturing a semiconductor device according to some embodiments of the disclosed concepts;

FIG. 15 is a diagram illustrating a method for manufacturing a semiconductor device according to some embodiments of the disclosed concepts;

FIG. 16 is a diagram illustrating a method for manufacturing a semiconductor device according to some embodiments of the disclosed concepts;

FIG. 17 is a diagram illustrating a method for manufacturing a semiconductor device according to some embodiments of the disclosed concepts; and

FIG. 18 is a diagram illustrating a method for manufacturing a semiconductor device according to some embodiments of the disclosed concepts.

### DETAILED DESCRIPTION

Hereinafter, embodiments of the disclosed concepts will be described with reference to the accompanying drawings in more detail in order to more specifically describe the disclosed concepts.

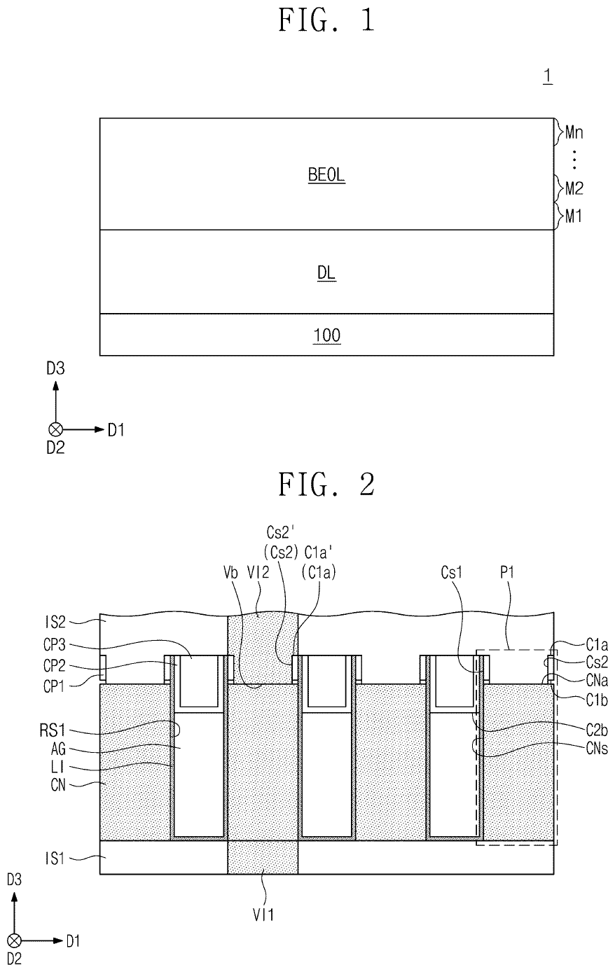

FIG. 1 is a cross-sectional view illustrating a semiconductor device 1 according to some embodiments of the disclosed concepts.

Referring to FIG. 1, the semiconductor device 1 may include a substrate 100. For example, the substrate 100 may be a semiconductor substrate including a semiconductor material like a silicon single crystal substrate, a silicon-germanium substrate, an SOI substrate. For another example, the substrate 100 may be an insulating substrate, and may include at least one of a silicon oxide (SiO₂) layer, a silicon nitride (SiN) layer or a silicon oxynitride (SiON) layer. In the present disclosure, each of the wordings, “A or B”, “at least one of A and B”, “at least one of A or B”, “A, B or C”, “at least one of A, B and C” and “at least one of A, B or C” may include any one or all possible combinations among items listed together with the corresponding phrase therein.

A first direction D1 and a second direction D2 may be substantially parallel to an upper surface of the substrate 100, and may cross one another. The first direction D1 and the second direction D2 may be perpendicular to one another. A third direction D3 may be vertical to the upper surface of the substrate 100, and may be perpendicular to each of the first direction D1 and the second direction D2.

An element layer DL may be provided on the substrate 100. The element layer DL may include at least one field effect transistor (FET). For example, the field effect transistor may be a metal-oxide-semiconductor field effect transistor (MOSFET), but embodiments of the disclosed concepts is not limited thereto.

A line layer BEOL may be provided on the element layer DL. The line layer BEOL may include a plurality of metal layers M1 to Mn. Each of the metal layers M1 to Mn may include a plurality of lines and vias. The line layer BEOL may be electrically connected to the element layer DL through the metal layers M1 to Mn. In addition, the line layer BEOL may electrically connect the element layer DL and an external input-output pad (not shown) through the metal layers M1 to Mn.

For example, although not shown on the drawing, a power transmission network layer (not shown) may be provided on a lower surface of the substrate 100. The power transmission network layer may include a plurality of lines. Accordingly, the power transmission network layer may transmit power to the element layer DL through a rear surface of the substrate 100. For example, the power transmission network layer may include a line network for applying a source voltage to the element layer DL. For example, the power transmission network layer may include a line network for applying a drain voltage to the element layer DL.

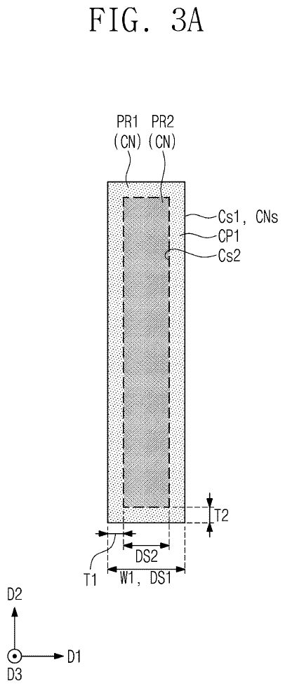

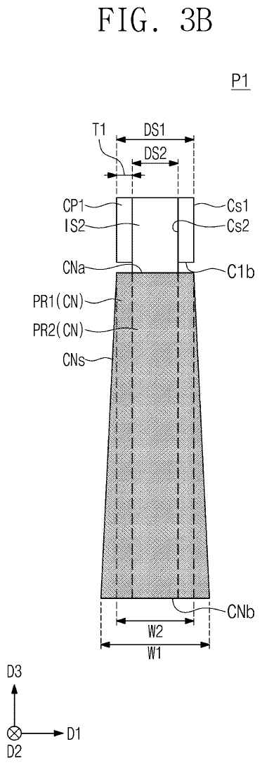

FIG. 2 is a cross-sectional view partially illustrating the line layer BEOL of the semiconductor device 1 of FIG. 1. FIG. 3A is a plan view illustrating a first capping pattern CP1 and a conductive pattern CN of FIG. 2. FIG. 3B is an enlarged diagram corresponding to P1 of FIG. 2, and specifically, is an enlarged diagram of the conductive pattern CN, the first capping pattern CP1 and a second insulating layer IS2.

Referring to FIGS. 1 and 2, FIG. 2 may be a cross-sectional view illustrating one metal layer among metal layers M1 to Mn of the line layer BEOL. For example, the metal layer of FIG. 2 may correspond to a first metal layer M1 among the metal layers M1 to Mn of the BEOL layer. In this case, a first via pattern VI1 to be described later may be connected to the element layer DL, and a second via pattern VI2 to be described later may be connected to a second metal layer M2. For another example, the metal layer of FIG. 2 may correspond to one of second to n-th metal layers M2 to Mn of the line layer BEOL. In this case, the first via pattern VI1 to be described later may be connected to a metal layer under the metal layer of FIG. 2, and the second via pattern VI2 to be described later may be connected to a metal layer over the metal layer of FIG. 2.

A first insulating layer IS1 including an insulating material may be provided on the element layer DL. For example, when the metal layer of FIG. 2 corresponds to the first metal layer M1, the first insulating layer IS1 may be interposed between the element layer DL and the conductive pattern CN to be described later of the first metal layer M1. For another example, when the metal layer of FIG. 2 corresponds to one of the second to n-th metal layers M2 to Mn, the first insulating layer IS1 may be interposed between the conductive pattern CN to be described later and the metal layer under the metal layer of FIG. 2.

The first via pattern VI1 may at least partially penetrate the first insulating layer IS1. The first via pattern VI1 may include first via patterns VI1 disposed spaced apart from one another in the first insulating layer IS1. Each of the first via patterns VI1 may be connected to a corresponding conductive pattern CN among the conductive patterns CN to be described later. For example, each of the first via patterns VI1 may include a conductive material.

The conductive pattern CN may be provided on the first insulating layer IS1. The conductive pattern CN may have a shape of a bar extending along the second direction D2, but embodiments of the disclosed concepts is not limited thereto. The shape of the conductive pattern CN may be variously changed according to a design of a layout of the metal layer. For example, the conductive pattern CN may include at least one of Ru, Cu, W, Co or Mo. The conductive pattern CN may include a plurality of conductive patterns CN disposed spaced apart from one another. The conductive patterns CN may be spaced apart from one another in the first direction D1, and although not shown on the drawing, may be spaced apart from one another in the second direction D2.

The first capping pattern CP1 may be provided on an upper surface CNa of the conductive pattern CN. The first capping pattern CP1 may be located at a vertically higher level than the conductive pattern CN. The first capping pattern CP1 may vertically overlap the conductive pattern CN. The first capping pattern CP1 may be spaced apart from the conductive pattern CN. Specifically, a lower surface C1b of the first capping pattern CP1 may be spaced apart from the upper surface CNa of the conductive pattern CN in the third direction D3. In this case, an air gap may be provided between the first capping pattern CP1 and the conductive pattern CN, or although not shown on the drawing, an insulating liner LI may be partially interposed between the first capping pattern CP1 and the conductive pattern CN.

The first capping pattern CP1 may include a material having etching selectivity with the conductive pattern CN. For example, the first capping pattern CP1 may include at least one of SiOC, SiO, AlO, AlN, AlSiN, AlSiO, HfO, TiO, TiN, SiN, SiON, SiC, SiCN or ZrO.

The first capping pattern CP1 may include a plurality of first capping patterns CP1. Each of the first capping patterns CP1 may vertically overlap a corresponding conductive pattern CN among the conductive patterns CN.

Referring to FIGS. 2, 3A and 3B, the conductive pattern CN may include a first region PR1 vertically overlapping the first capping pattern CP1, and a second region PR2 surrounded by the first region PR1. The second region PR2 of the conductive pattern CN may not vertically overlap the first capping pattern CP1. On a plan view, the first capping pattern CP1 may surround the second region PR2 of the conductive pattern CN. On a plan view, a side surface CNs of the conductive pattern CN may follow a profile of an outer side surface Cs1 of the first capping pattern CP1. In other words, on a plan view, a profile of the side surface CNs of the conductive pattern CN may be the same as/similar to the profile of the outer side surface Cs1 of the first capping pattern CP1.

With respect to the first direction D1, a lower surface CNb of the conductive pattern CN may have a first width W1, and the upper surface CNa of the conductive pattern CN may have a second width W2. FIG. 2 illustrates that the first width W1 and the second width W2 are substantially the same as one another, but embodiments of the disclosed concepts is not limited thereto. As illustrated in FIG. 3B, the first width W1 may be greater than the second width W2. A width along the first direction D1 of the conductive pattern CN may become greater in a downward direction (in other words, in an opposite direction of the third direction D3). A profile of the width of the conductive pattern CN described above may be caused by characteristics of a process of forming the conductive pattern CN (for example, characteristics of dry etching) to be described later.

With respect to the first direction D1, a first distance DS1 between the outer side surfaces Cs1 of the first capping pattern CP1 may be smaller than the first width W1, and may be substantially the same as the second width W2. With respect to the first direction D1, a second distance DS2 between an inner side surfaces Cs2 of the first capping pattern CP1 may be smaller than each of the first width W1 and the second width W2. The first capping pattern CP1 may have a first thickness T1 with respect to the first direction D1, and a second thickness T2 with respect to the second direction D2. The first thickness T1 and the second thickness T2 may be respectively smaller than the first width W1 and the second width W2. The first thickness T1 may be approximately the same as the second thickness T2.

Referring back to FIG. 2, a first recess RS1 may be defined between the conductive patterns CN. An insulating liner LI including an insulating material may conformally cover an inner surface of the first recess RS1. The insulating liner LI may cover the outer side surface Cs1 of the first capping pattern CP1, and may extend onto the side surface CNs of the conductive pattern CN. The insulating liner LI may be partially interposed between a second capping pattern CP2 to be described later and the first capping pattern CP1.

Each of a third capping pattern CP3 and the second capping pattern CP2 including an insulating material may be provided to an upper portion of the first recess RS1. The second capping pattern CP2 may be provided on the outer side surface Cs1 of the first capping pattern CP1. The second capping pattern CP2 may conformally partially cover a side surface of the insulating liner LI. The third capping pattern CP3 may be provided in the second capping pattern CP2. The second capping pattern CP2 may conformally cover a side surface and a lower surface of the third capping pattern CP3.

An air gap AG may be provided between the first insulating layer IS1 and the second capping pattern CP2. The air gap AG may be provided between the conductive patterns CN. For example, the air gap AG may have a dielectric constant of 0. In the present specification, the air gap AG may be defined by a boundary of solids, and may mean some region filled with a vapor-phase material. For another example, the air gap AG may mean an empty space. For example, the air gap AG may be defined by the second capping pattern CP2 and the insulating liner LI. For another example, when the insulating liner LI is omitted, the air gap AG may be defined by the second capping pattern CP2 and the conductive patterns CN.

It is illustrated in the drawing that an uppermost end of the air gap AG is located at a vertically lower level than the upper surface CNa of the conductive pattern CN, but embodiments of the disclosed concepts is not limited thereto. According to a position of a lower surface C2b of the second capping pattern CP2, the vertical level of the uppermost end of the air gap AG may be changed.

Although not shown on the drawing, whether or not the insulating liner LI, the second capping pattern CP2, the third capping pattern CP3 and the air gap AG described above are present may be variously changed. For example, although not shown on the drawing, the insulating liner LI, the second capping pattern CP2, the third capping pattern CP3 and the air gap AG described above may be omitted. In this case, the first recess RS1 may be filled with a separate insulating layer.

A second insulating layer IS2 including an insulating material may be provided on the conductive pattern CN. The second insulating layer IS2 may be interposed between the conductive pattern CN and a metal layer on the metal layer of FIG. 2. The second insulating layer IS2 may be partially inserted between the inner side surfaces Cs2 of the first capping pattern CP1. A lower surface of the second insulating layer IS2 may be located at a vertically lower level than the lower surface C1b of the first capping pattern CP1. The second insulating layer IS2 may cover an upper surface C1a and the inner side surfaces Cs2 of the first capping pattern CP1. The second insulating layer IS2 may cover the upper surface CNa (for example, an upper surface of the second region PR2 of the conductive pattern CN) of the conductive pattern CN. The second insulating layer IS2 may cover the upper surface of each of the third capping pattern CP3 and the second capping pattern CP2.

The second via pattern VI2 may be provided in the second insulating layer IS2. The second via pattern VI2 may at least partially penetrate the second insulating layer IS2. The second via pattern VI2 may be partially inserted between the inner side surfaces Cs2 of the first capping pattern CP1. A lower surface Vb of the second via pattern VI2 may be located at a vertically lower level than the lower surface C1b of the first capping pattern CP1. The second via pattern VI2 may cover the upper surface CNa (for example, the upper surface of the second region PR2 of the conductive pattern CN) of the conductive pattern CN. For example, the second via pattern VI2 may cover portions Cs2′ of the inner side surfaces Cs2 of the first capping pattern CP1 and a portion C1a′ of the upper surface Cla of the first capping pattern CP1.

The second via pattern VI2 may include second via patterns VI2 disposed spaced apart from one another in the second insulating layer IS2. Each of the second via patterns VI2 may be connected to a corresponding conductive pattern CN among the conductive patterns CN. For example, each of the second via patterns VI2 may include a conductive material.

As described above, the metal layer of FIG. 2 may correspond to any one metal layer among the metal layers M1 to Mn of the line layer BEOL, but embodiments of the disclosed concepts is not limited thereto. Characteristics of the metal layer described with reference to FIG. 2 may be identically/similarly applied to other metal layers among the metal layers M1 to Mn of the line layer BEOL.

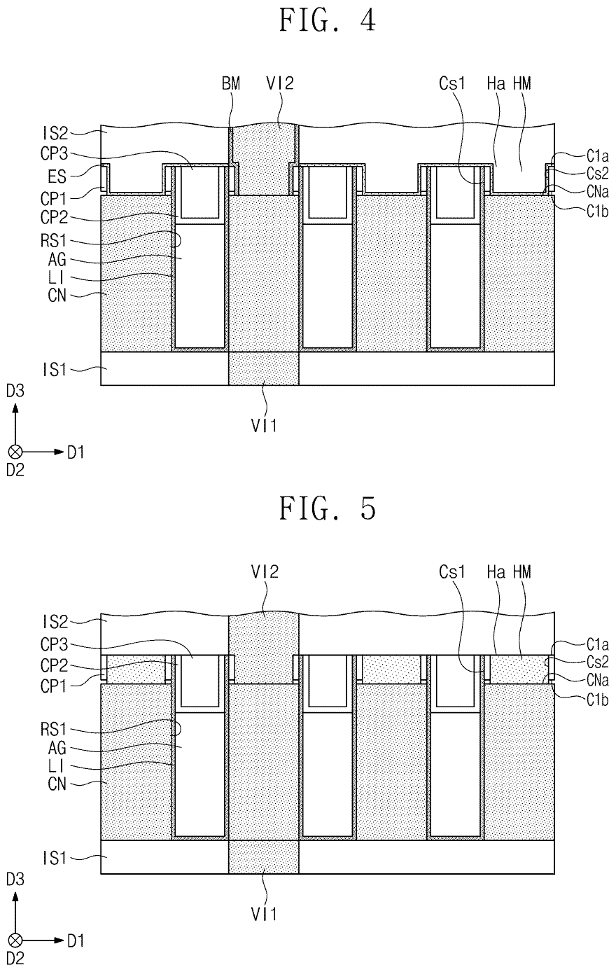

Hereinafter, a semiconductor device according to other embodiments of the disclosed concepts will be described with reference to FIGS. 4 to 7. For simplification of description, duplicate description of that described above will be omitted, and a difference from that described above will be mainly described.

FIG. 4 is a cross-sectional view partially illustrating the line layer BEOL of the semiconductor device 1 of FIG. 1.

Referring to FIG. 4, an etch stop layer ES may be interposed between the second insulating layer IS2 and the conductive pattern CN, and between the second insulating layer IS2 and the third capping pattern CP3. A barrier pattern BM may be interposed between the second via pattern VI2 and the second insulating layer IS2, and between the second via pattern VI2 and the first capping pattern CP1.

FIG. 5 is a cross-sectional view partially illustrating the line layer BEOL of the semiconductor device 1 of FIG. 1.

Referring to FIG. 5, a hard mask pattern HM may be provided on the upper surface CNa of the conductive pattern CN. The hard mask pattern HM may vertically overlap the second region PR2 (see FIG. 3) of the conductive pattern CN. The hard mask pattern HM may be inserted between the inner side surfaces Cs2 of the first capping pattern CP1. The hard mask pattern HM may be surrounded by the first capping pattern CP1. The inner side surface Cs2 of the first capping pattern CP1 may follow a profile of a side surface of the hard mask pattern HM. The hard mask pattern HM may be spaced apart from the insulating liner LI with the first capping pattern CP1 therebetween.

An upper surface Ha of the hard mask pattern HM may be substantially coplanar with the upper surface C1a of the first capping pattern CP1. The upper surface Ha of the hard mask pattern HM may be covered with the second insulating layer IS2. A lower surface of the hard mask pattern HM may be located at a vertically lower level than the lower surface C1b of the first capping pattern CP1. The lower surface of the hard mask pattern HM may be in contact with the upper surface CNa of the conductive pattern CN.

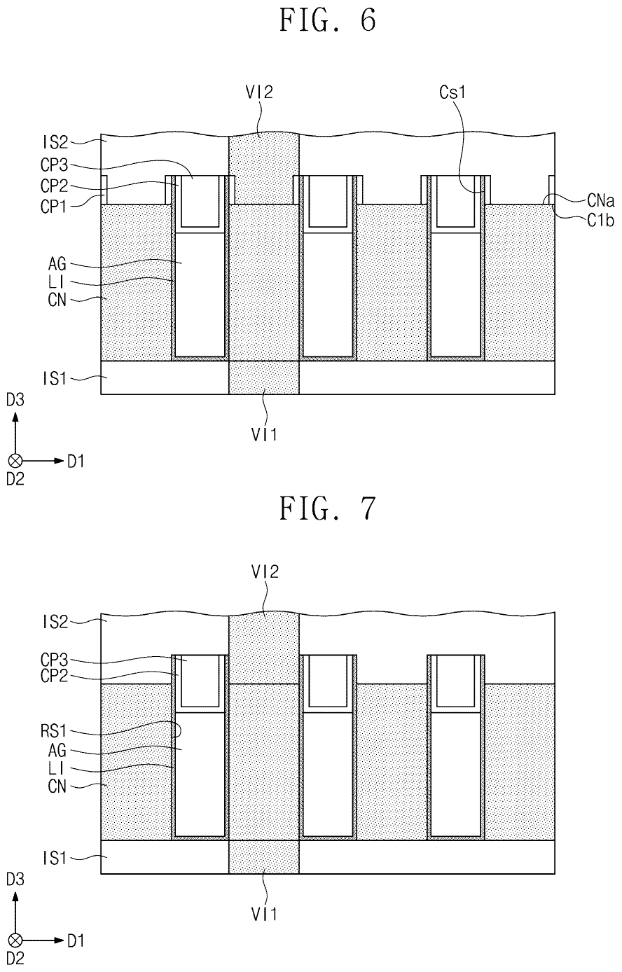

FIG. 6 is a cross-sectional view partially illustrating the line layer BEOL of the semiconductor device 1 of FIG. 1.

Referring to FIG. 6, the lower surface C1b of the first capping pattern CP1 may be in contact with the upper surface CNa of the conductive pattern CN. The lower surface C1b of the first capping pattern CP1 may be located at the substantially same vertical level as the upper surface CNa of the conductive pattern CN.

FIG. 7 is a cross-sectional view partially illustrating the line layer BEOL of the semiconductor device 1 of FIG. 1.

Referring to FIG. 7, unlike what is described with reference to FIG. 2, the first capping pattern CP1 may not be provided. The second insulating layer IS2 may be partially inserted into the insulating liner LI. The second insulating layer IS2 may be in partial contact with a side surface of the insulating liner LI.

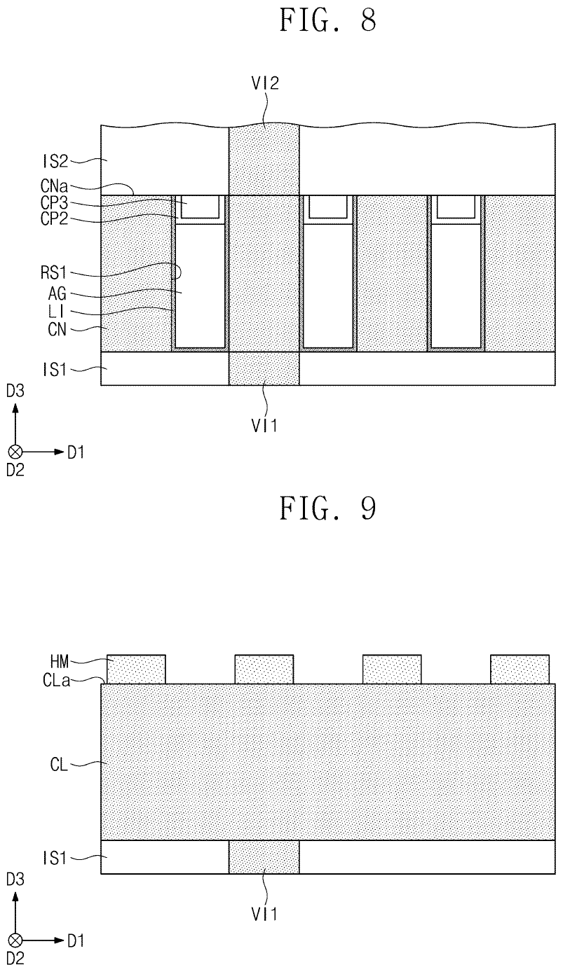

FIG. 8 is a cross-sectional view partially illustrating the line layer BEOL of the semiconductor device 1 of FIG. 1.

Referring to FIG. 8, unlike what is described with reference to FIG. 2, the first capping pattern CP1 may not be provided. In addition, unlike what is described with reference to FIG. 2, the upper surface CNa of the conductive pattern CN may be substantially coplanar with an upper surface of each of the insulating liner LI, the second capping pattern CP2 and the third capping pattern CP3.

Hereinafter, a method for manufacturing a semiconductor device according to some embodiments of the disclosed concepts will be described with reference to FIGS. 9 to 18. For simplification of description, duplicate description of that described above will be omitted, and a difference from that described above will be mainly described.

FIGS. 9 to 14 are diagrams illustrating a method for manufacturing the semiconductor device 1 according to some embodiments of the disclosed concepts. Specifically, FIGS. 9 to 14 are cross-sectional views partially illustrating the line layer BEOL of the semiconductor device 1 of FIG. 1.

Referring to FIG. 9, the first insulating layer IS1 may be formed on the substrate 100. The first via pattern VII may be formed in the first insulating layer IS1.

After forming the substrate 100 and before forming the first insulating layer IS1, the element layer DL may be formed on the substrate 100. For example, when a metal layer of FIG. 9 is the first metal layer M1 (see FIG. 1), the first insulating layer IS1 may be formed on the element layer DL. For another example, when the metal layer of FIG. 9 is one among the second to n-th metal layers M2 to Mn (see FIG. 1), the first insulating layer IS1 may be formed on the metal layer thereunder.

A conductive layer CL may be formed on the first insulating layer IS1. Hard mask patterns HM may be formed on the conductive layer CL. For example, forming the hard mask patterns HM may include forming a hard mask layer (not shown) on an upper surface CLa of the conductive layer CL, and dividing the hard mask layer (not shown) into a plurality of hard mask patterns HM by patterning the hard mask layer. For example, each of the hard mask patterns HM may include at least one of SiOC, SiO, AlO, AlN, AlSiN, AlSiO, HfO, TiO, TiN, SiN, SiON, SiC, SiCN or ZrO.

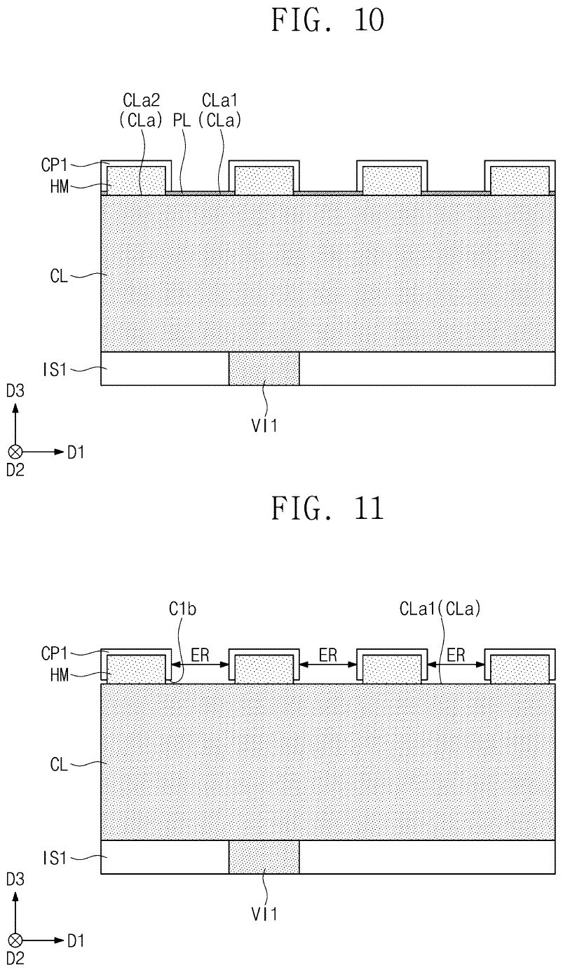

Referring to FIG. 10, the upper surface CLa of the conductive layer CL may have a first upper surface CLa1 exposed to the outside and a second upper surface CLa2 covered by the hard mask patterns HM. A protective layer PL may be formed to cover the first upper surface CLa1 of the conductive layer CL. In other words, the protective layer PL may be formed so as to cover the upper surface CLa of the conductive layer CL not covered by the hard mask patterns HM. For example, the protective layer PL may include a first material, but embodiments of the disclosed concepts is not limited thereto. The protective layer PL may include the first material and a second material. For example, the first material may include at least one of carbon, hydrogen or oxygen. For example, the second material may include at least one of nitrogen, halogen, sulfur or silicon.

For example, forming the protective layer PL may include performing a selective deposition process. Accordingly, the protective layer PL may be selectively formed on the first upper surface CLal of the conductive layer CL. Accordingly, the protective layer PL may not cover a portion of a side surface and an upper surface of the first capping pattern CP1. As a result, the portion of the side surface and the upper surface of the first capping pattern CP1 may be exposed to the outside.

Thereafter, the first capping patterns CP1 may be formed so as to cover side surfaces and upper surfaces of the hard mask patterns HM. For example, the first capping pattern CP1 may be formed so as to conformally cover the side surface and the upper surface of the hard mask pattern HM. The first capping patterns CP1 may be spaced apart from the conductive layer CL by the protective layer PL.

For example, forming the first capping pattern CP1 may include performing a selective deposition process. The first capping pattern CP1 may be selectively formed on the upper surface and the side surface of the hard mask pattern HM. Accordingly, without performing a separate patterning process, the first capping patterns CP1 may be formed on the hard mask patterns HM, and may be spaced apart from one another.

Referring to FIG. 11, the protective layer PL may be removed, and exposure regions ER may be formed between the first capping patterns CP1. The first upper surface CLa1 of the conductive pattern CN may be exposed to the outside by the exposure regions ER.

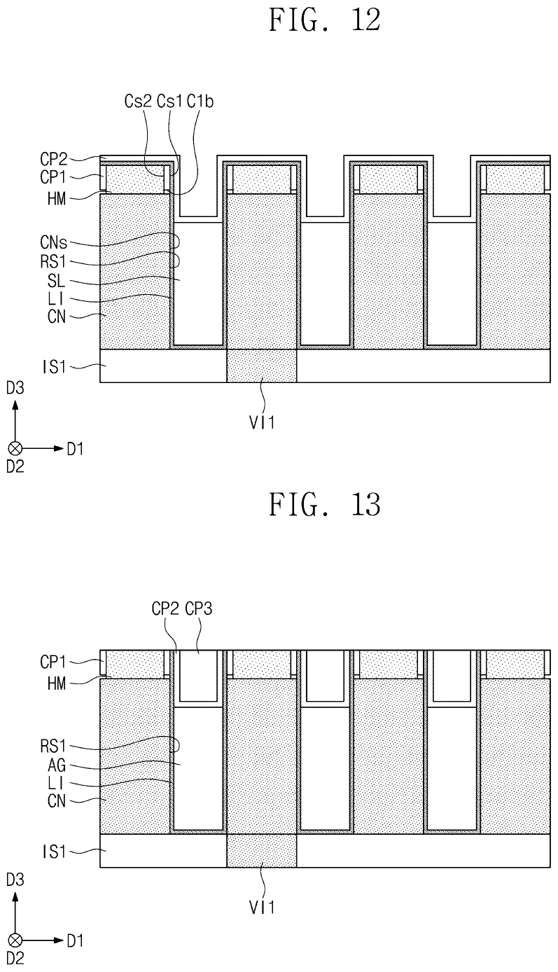

Referring to FIG. 12, the conductive patterns CN may be formed on the first insulating layer IS1. Forming the conductive patterns CN may include dividing the conductive layer CL (see FIG. 11) into the conductive patterns CN by partially removing the conductive layer CL (see FIG. 11) through paths of the exposure regions ER (see FIG. 11) by using the hard mask patterns HM and the first capping patterns CP1 as masks.

The first capping pattern CP1 may include a material having etching selectivity with the conductive layer CL (see FIG. 11). Accordingly, when the conductive layer CL (see FIG. 11) is removed, the first capping pattern CP1 may be removed relatively little. For example, as illustrated on the drawing, the first capping pattern CP1 covering the upper surface of the hard mask pattern HM may be removed in a process of removing the conductive layer CL (see FIG. 11), but embodiments of the disclosed concepts is not limited thereto. For another example, although not shown on the drawing, the first capping pattern CP1 may cover the upper surface of the hard mask pattern HM even after the process of removing the conductive layer CL (see FIG. 11). In this case, a thickness of a portion of the first capping pattern CP1 covering the upper surface of the hard mask pattern HM may be smaller than a thickness of any other portion of the first capping pattern CP1 covering the side surface of the hard mask pattern HM.

According to the disclosed concepts, before a process of forming the conductive patterns CN, the first capping pattern CP1 may be formed so as to cover the upper surface and the side surface of the hard mask pattern HM. Accordingly, during a process of removing the conductive layer CL (see FIG. 11), the first capping pattern CP1 may cover the upper surface of the hard mask pattern HM to protect the hard mask pattern HM. Accordingly, during the process of removing, the first capping pattern CP1 may serve to protect the hard mask pattern HM so that the hard mask pattern HM may not be removed, or may be removed less than a case in which the first capping pattern CP1 is not provided.

When the first capping pattern CP1 is not provided, the hard mask pattern HM may be removed together in the process of removing the conductive layer CL (see FIG. 11). Accordingly, in a case in which the hard mask pattern HM serves as a planarization stop layer in a planarization process to be described later, when the hard mask pattern HM becomes higher, the planarization process may be easily performed. However, when the hard mask pattern HM becomes higher, a process of patterning the hard mask layer may not be easy, thereby causing a process defect. When in order to make the process of patterning the hard mask layer easy, the hard mask pattern HM becomes lower, the hard mask pattern HM may be removed together during the process of removing the conductive layer CL (see FIG. 11) not to secure a height of the hard mask pattern HM capable of serving as the planarization stop layer described above.

Unlike this, according to the disclosed concepts, during the process of removing the conductive layer CL (see FIG. 11) that forms the conductive pattern CN, the first capping pattern CP1 may protect the hard mask pattern HM. Accordingly, the hard mask pattern HM may be formed so as to have a relatively smaller height. As a result, the process of patterning the hard mask layer that forms the hard mask pattern HM may become easier. In addition, even after the process of removing the conductive layer CL (see FIG. 11), the thickness of the hard mask pattern HM that serves as the planarization stop layer of the planarization process to be performed may be maintained. Accordingly, productivity of the semiconductor device may be improved.

In addition, since the first capping patterns CP1 are selectively formed on the upper surfaces and the side surfaces of the hard mask patterns HM, the exposure regions ER (see FIG. 11) for a process of partially removing the conductive layer CL (see FIG. 11) may be secured without a separate additional process of removing the first capping patterns CP1. When the first capping patterns CP1 are formed without performing a process of selectively depositing the first capping patterns CP1, the first capping patterns CP1 may be formed so as to cover the entire upper surface of the protective layer PL (see FIG. 10) as well as the upper surfaces and the side surfaces of the hard mask patterns HM. In this case, in order to form the exposure regions ER (see FIG. 11), a process of additionally removing the first capping patterns CP1 must be accompanied. However, due to the process of additionally removing, the first capping pattern CP1 covering the upper surface of the hard mask pattern HM may be partially removed together. Accordingly, the upper surface of the hard mask pattern HM may be exposed, and the first capping pattern CP1 does not protect the hard mask pattern HM during the process of removing the conductive layer CL (see FIG. 11).

According to the disclosed concepts, the first capping patterns CP1 may be formed so as to cover the upper surfaces and the side surfaces of the hard mask patterns HM in the selective deposition process. Accordingly, without the process of additionally removing the first capping patterns CP1, the first capping patterns CP1 may cover the upper surfaces of the hard mask patterns HM, and simultaneously, the exposure regions ER (see FIG. 11) for the process of partially removing the conductive layer CL (see FIG. 11) may be secured. Accordingly, productivity of the semiconductor device may be improved.

Thereafter, the insulating liner LI conformally covering a sidewall of the first recess RS1, the outer side surfaces Cs1 of the first capping patterns CP1 and the upper surfaces of the hard mask patterns HM may be formed. A sacrificial layer SL may be formed in the first recess RS1. The sacrificial layer SL may include a material having characteristics of being decomposed by heat. For example, the sacrificial layer SL may include carbon (C). The second capping pattern CP2 conformally covering an upper surface of the sacrificial layer SL, and the insulating liner LI may be formed.

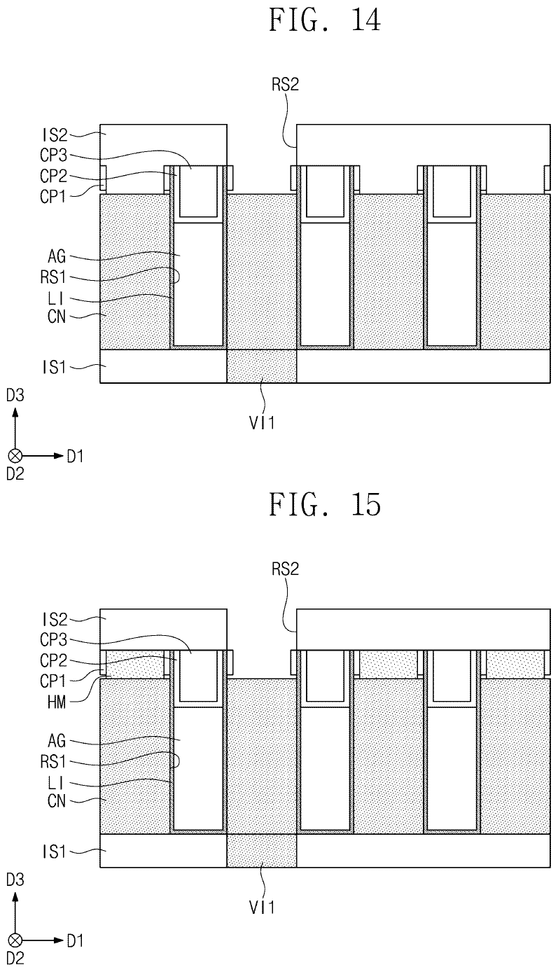

Referring to FIG. 13, the third capping pattern CP3 may be formed on the second capping pattern CP2. Thereafter, a process of planarizing the insulating liner LI, the second capping pattern CP2 and the third capping pattern CP3 may be performed. The hard mask patterns HM may be utilized as the planarization stop layer during the planarization process. As described with reference to FIG. 12, the first capping pattern CP1 may protect the hard mask patterns HM during the process of forming the conductive pattern CN not to unnecessarily remove the hard mask patterns HM. Accordingly, the hard mask patterns HM may be appropriately utilized as the planarization stop layer during the planarization process described above. For example, after the planarization process, the upper surfaces of the hard mask patterns HM may be exposed to the outside.

Referring to FIG. 14, the hard mask patterns HM may be removed. Thereafter, the second insulating layer IS2 may be formed on the conductive pattern CN. A second recess RS2 may be formed in the second insulating layer IS2. An upper surface of the conductive pattern CN may be exposed to the outside by the second recess RS2.

Referring back to FIGS. 1 and 2, the second via pattern VI2 may be formed in the second recess RS2.

FIG. 15 is a diagram illustrating a method for manufacturing the semiconductor device 1 according to some embodiments of the disclosed concepts. Specifically, FIG. 15 is a cross-sectional view partially illustrating the line layer BEOL of the semiconductor device 1 of FIG. 1.

Referring to FIG. 15, unlike what is described with reference to FIG. 14, the hard mask patterns HM may not be removed. Accordingly, the hard mask patterns HM may remain on the conductive pattern CN. Thereafter, the second insulating layer IS2 may be formed on the hard mask patterns HM.

Thereafter, the semiconductor device 1 described with reference to FIG. 5 may be manufactured by using the method for manufacturing the semiconductor device 1 described above.

FIG. 16 is a diagram illustrating the method for manufacturing the semiconductor device 1 according to some embodiments of the disclosed concepts. Specifically, FIG. 16 is a cross-sectional view partially illustrating the line layer BEOL of the semiconductor device 1 of FIG. 1.

Referring to FIG. 16, the protective layer PL may be formed with a smaller thickness than the protective layer PL described with reference to FIG. 10. Accordingly, the protective layer PL may not be formed on or may be formed little on some portions, of the first upper surface CLal of the conductive pattern CN, adjacent to the side surfaces of the hard mask patterns HM. Accordingly, the first capping patterns CP1 may be in contact with the first upper surface CLa1 of the conductive pattern CN.

Thereafter, the semiconductor device 1 described with reference to FIG. 6 may be manufactured by using the method for manufacturing the semiconductor device 1 described above.

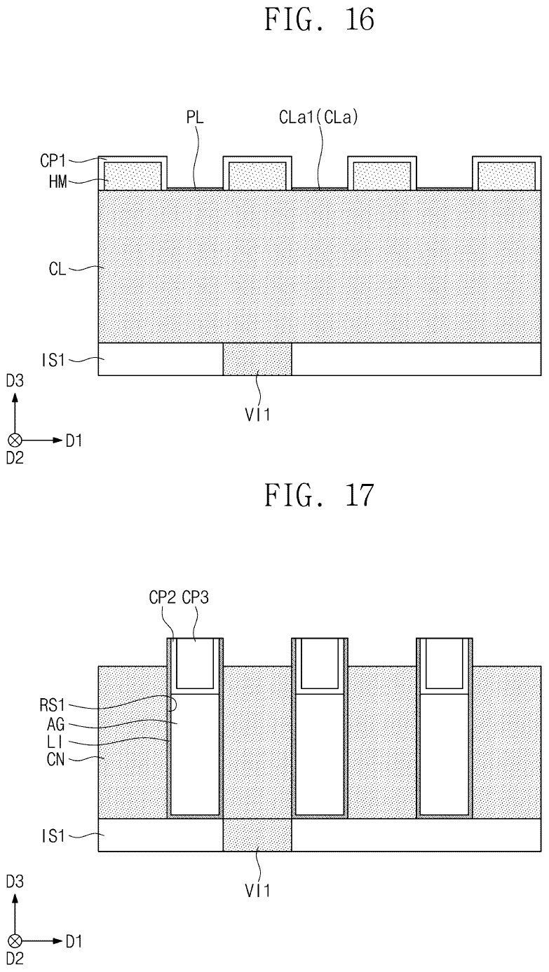

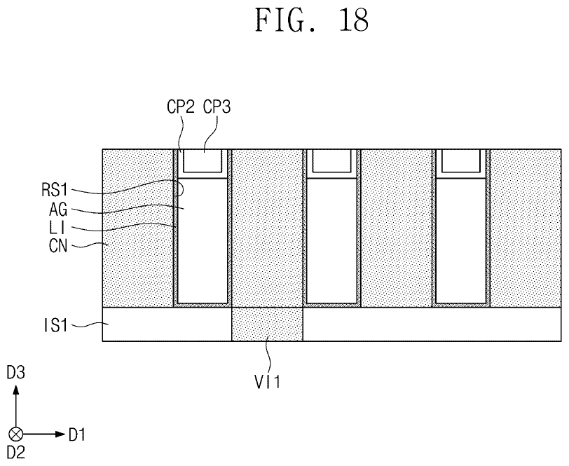

FIG. 17 is a diagram illustrating the method for manufacturing the semiconductor device 1 according to some embodiments of the disclosed concepts. Specifically, FIG. 17 is a cross-sectional view partially illustrating the line layer BEOL of the semiconductor device 1 of FIG. 1.

Referring to FIG. 17, after the planarization process described with reference to FIG. 13, the hard mask patterns HM and the first capping patterns CP1 may be removed. Thereafter, the second insulating layer IS2 may be formed on the conductive pattern CN.

Thereafter, the semiconductor device 1 described with reference to FIG. 7 may be manufactured by using the method for manufacturing the semiconductor device 1 described above.

FIG. 18 is a diagram illustrating the method for manufacturing the semiconductor device 1 according to some embodiments of the disclosed concepts. Specifically, FIG. 18 is a cross-sectional view partially illustrating the line layer BEOL of the semiconductor device 1 of FIG. 1.

Referring to FIG. 18, due to the planarization process described with reference to FIG. 13, the hard mask patterns HM and the first capping patterns CP1 may be removed. In this case, the conductive pattern CN may be utilized as the planarization stop layer of the planarization process. Thereafter, the second insulating layer IS2 may be formed on the conductive pattern CN.

Thereafter, the semiconductor device 1 described with reference to FIG. 8 may be manufactured by using the method for manufacturing the semiconductor device 1 described above.

According to the disclosed concepts, during a process of removing a conductive layer for forming a conductive pattern, a capping pattern may cover an upper surface of a hard mask pattern, and may protect the hard mask pattern. Accordingly, the hard mask pattern may be formed so as to have a relatively smaller height. As a result, a process of patterning the hard mask layer for forming the hard mask pattern may become easier. In addition, even after a process of removing the conductive layer, a thickness of the hard mask pattern for serving as a planarization stop layer of a planarization process to be performed may be maintained. Accordingly, productivity of a semiconductor device may be improved.

According to the disclosed concepts, the capping patterns may be formed so as to cover the upper surfaces and the side surfaces of the hard mask patterns in a selective deposition process. Accordingly, without a process of additionally removing the capping patterns, the capping patterns may cover the upper surfaces of the hard mask patterns, and simultaneously, exposure regions for the process of removing the conductive layer may be secured. Accordingly, productivity of the semiconductor device may be improved.

The above description of embodiments of the disclosed concepts provides an example for description of the disclosed concepts. Therefore, the disclosed concepts is not limited to the above embodiments, and it is obvious that various modifications and changes such as combining the above embodiments may be made by those skilled in the art within the technical spirit of the disclosed concepts.

What is claimed is:

1. A semiconductor device comprising:
a first insulating layer on a substrate;
a conductive pattern on the first insulating layer; and
a first capping pattern on an upper surface of the conductive pattern,
wherein the conductive pattern includes:
a first region vertically overlapping the first capping pattern; and
a second region surrounded by the first region, and
with respect to a first direction parallel to an upper surface of the substrate, a first distance between outer side surfaces of the first capping pattern is less than a first width of a lower surface of the conductive pattern.

2. The semiconductor device of claim 1, wherein with respect to the first direction, a second distance between inner side surfaces of the first capping pattern is less than a second width of the upper surface of the conductive pattern.

3. The semiconductor device of claim 1, wherein the second region of the conductive pattern does not vertically overlap the first capping pattern.

4. The semiconductor device of claim 1, wherein the first capping pattern has a first thickness with respect to the first direction,
the first capping pattern has a second thickness with respect to a second direction crossing the first direction, and substantially parallel to the upper surface of the substrate, and
the first thickness is approximately the same as the second thickness.

5. The semiconductor device of claim 1, wherein a lower surface of the first capping pattern is spaced apart from the upper surface of the conductive pattern.

6. The semiconductor device of claim 1, wherein on a plan view, the first capping pattern is located in the conductive pattern.

7. The semiconductor device of claim 1, further comprising an insulating liner covering the outer side surfaces of the first capping pattern, and extending onto a side surface of the conductive pattern.

8. The semiconductor device of claim 1, further comprising a via pattern on the upper surface of the conductive pattern, wherein a lower surface of the first capping pattern is located at a vertically higher level than a level of a lower surface of the via pattern.

9. The semiconductor device of claim 1, further comprising a via pattern on the upper surface of the conductive pattern,
wherein an upper surface of the first capping pattern is located at a vertically lower level than a level of an upper surface of the via pattern.

10. The semiconductor device of claim 1, further comprising:
a second insulating layer on the conductive pattern; and
a via pattern penetrating at least a portion of the second insulating layer, and being on the upper surface of the conductive pattern,
wherein a portion of the second insulating layer is inserted between inner side surfaces of the first capping pattern.

11. The semiconductor device of claim 1, further comprising:
a second insulating layer on the conductive pattern; and
a via pattern penetrating at least a portion of the second insulating layer, and being on the upper surface of the conductive pattern,
wherein a portion of the via pattern is inserted between inner side surfaces of the first capping pattern.

12. The semiconductor device of claim 1, further comprising a hard mask pattern on the upper surface of the conductive pattern,
wherein the hard mask pattern is interposed between inner side surfaces of the first capping pattern.

13. The semiconductor device of claim 1, further comprising:
a second capping pattern on a side surface of the first capping pattern; and
an air gap between the second capping pattern and the first insulating layer, and on a side surface of the conductive pattern.

14. The semiconductor device of claim 1, wherein the first capping pattern comprises at least one of SiOC, SiO, AlO, AlN, AlSiN, AlSiO, HfO, TiO, TiN, SiN, SiON, SiC, SiCN or ZrO.

15. A semiconductor device comprising:
a first insulating layer on a substrate;
a conductive pattern on the first insulating layer; and
a first capping pattern vertically overlapping the conductive pattern on an upper surface of the conductive pattern,
wherein with respect to a first direction substantially parallel to an upper surface of the substrate, a first distance between outer side surfaces of the first capping pattern is less than a first width of a lower surface of the conductive pattern, and
with respect to the first direction, a second distance between inner side surfaces of the first capping pattern is less than a second width of the upper surface of the conductive pattern.

16. The semiconductor device of claim 15, wherein a lower surface of the first capping pattern is spaced apart from the upper surface of the conductive pattern.

17. The semiconductor device of claim 15, further comprising:
a second insulating layer on the conductive pattern; and
a via pattern penetrating at least a portion of the second insulating layer,
wherein another portion of the second insulating layer is inserted between the inner side surfaces of the first capping pattern.

18. The semiconductor device of claim 17, wherein a portion of the via pattern is inserted between the inner side surfaces of the first capping pattern.

19. The semiconductor device of claim 15, wherein on a plan view, the first capping pattern is located in the conductive pattern.

20. A semiconductor device comprising:
an element layer on a substrate; and
a line layer on the element layer,
wherein the line layer includes:
a first insulating layer on the element layer;
a conductive pattern on the first insulating layer;
a first capping pattern on an upper surface of the conductive pattern;
a second capping pattern on a side surface of the first capping pattern; and
an air gap between the second capping pattern and the first insulating layer, and on a side surface of the conductive pattern,
the conductive pattern includes:
a first region vertically overlapping the first capping pattern; and
a second region surrounded by the first region, and
with respect to a first direction parallel to an upper surface of the substrate, a first distance between outer side surfaces of the first capping pattern is less than a first width of a lower surface of the conductive pattern.
